(19) United States
(12) Patent Application Publication
(10) Pub. No.: US 2025/0075926 A1
(43) Pub. Date: Mar. 6, 2025

(54) DIAGNOSTIC METHOD OF CROSS-WIRE FAULT

(71) Applicant: Intellihot, Inc., Galesburg, IL (US)

(72) Inventors: Sridhar Deivasigamani, Mundelein, IL (US); Sivaprasad Akasam, Round Rock, TX (US)

(21) Appl. No.: 18/950,001

(22) Filed: Nov. 16, 2024

Related U.S. Application Data
(63) Continuation-in-part of application No. 17/699,125, filed on Mar. 20, 2022.

(51) Int. Cl. F24F 11/38

(52) U.S. Cl. CPC F24F 11/38

(57) ABSTRACT

A diagnostic method of a system having at least one device under test and at least one peripheral device, the diagnostic method including obtaining a response of a test action conducted on the at least one device under test; and obtaining a response of a test action conducted on the at least one peripheral device; wherein if both the response of the test action conducted on the at least one device under test deviates from an expected result based on the test action conducted on the at least one device under test and the response of the test action conducted on the at least one peripheral device deviates from an expected result based on the test action conducted on the at least one peripheral device, a cross-wire fault is raised.

### PRIORITY CLAIM AND RELATED APPLICATIONS

This continuation-in-part application claims the benefit of priority from non-provisional application Ser. No. 17/699,125 filed on Mar. 20, 2022. Said application is incorporated by reference in its entirety.

### BACKGROUND OF THE INVENTION

### 1. The Field of the Invention

The present invention relates generally to a diagnostic method for detecting a cross-wire fault. More specifically, the present invention is directed to a diagnostic method for detecting a cross-wire fault and identifying one or more device and/or one or more component responsible for the cross-wire fault.

### 2. Background Art

Traditional failure mode detection means are targeted on the performance of specific devices and/or components in question for a more accurate detection of failure modes or identification of devices and/or components responsible for the failure/s. For instance, in order to identify a failure mode associated with the process of water heating of a water heater or the equipment associated with heating in a water heater, various components of the water heater are monitored as the failure of any one of the components may contribute to the failure in water heating. Typical components found in a water or fluid heating system include one or more blowers, igniters, burners, pumps, heat exchangers and various flow valves, etc. The failure of one of these components can be sufficient to cause a water heater to fail and requires an effective diagnostic method to properly identify the failed component and its root cause of failure. However, even an effective but heater-centric diagnostic method is not useful for detecting a cross-wire fault. A mis-wiring or cross-wire event can cause highly unusual behaviors to be exhibited in a monitored device or component. Lacking an effective diagnostic tool or method for detecting a cross-wire fault, the realization of the existence of a cross-wire fault typically falls on the shoulders of alert, highly-skilled and experienced service personnel who are capable in noticing unusual behaviors exhibited in one or more devices that are outside of the device or component being monitored.

There exists a need for a diagnostic method capable of detecting a cross-wire fault and identifying devices or components responsible for the cross-wire fault such that a service action can be taken quickly and a service action that is focused on the appropriate devices or components in question.

### SUMMARY OF THE INVENTION

In accordance with the present invention, there is provided a diagnostic method of a system having a controller, two or more heating devices each having a heat exchanger, a valve disposed upstream of the heat exchanger, and a temperature sensor disposed downstream of the heat exchanger, the diagnostic method including, using the controller to:
(a) identify active heating devices of the two or more heating devices in the system to result in two or more active heating devices;
(b) determine at least one test to be performed on the two or more active heating devices, the at least one test involves a unique pairing of the two or more active heating devices, wherein the unique pairing includes a first heating device including a first valve and a first temperature sensor and a second heating device including a second valve and a second temperature sensor;
(c) send a first command to open the first valve, obtain a response of the first heating device as indicated by the first temperature sensor to the first command and determine the existence of a first temperature rise as indicated by the first temperature sensor, wherein if the first temperature rise does not exist, a first deviation exists; and
(d) send a second command to open the second valve, obtain a response of the second heating device as indicated by the second temperature sensor to the second command and determine the existence of a second temperature rise as indicated by the second temperature sensor, wherein if the second temperature rise does not exist, a second deviation exists, wherein if both the first deviation and the second deviation exist, a cross-wire fault is raised and if only one of the first deviation and the second deviation exists, a device under test fault is raised; and
(e) repeat steps (c)-(d) until the at least one test has been completed.

In one embodiment, the diagnostic method further includes sending a first command to open the first valve as part of a normal operation of the first valve. In one embodiment, the diagnostic method further includes sending a first command to open the first valve as part of an exerciser.

An object of the present invention is to provide a diagnostic method configured for not only detecting problems with parts or components specific to a specific module under diagnosis but also faults that occur due to components not specific to the specific module under diagnosis or “cross-wire” faults.

Whereas there may be many embodiments of the present invention, each embodiment may meet one or more of the foregoing recited objects in any combination. It is not intended that each embodiment will necessarily meet each objective. Thus, having broadly outlined the more important features of the present invention in order that the detailed description thereof may be better understood, and that the present contribution to the art may be better appreciated, there are, of course, additional features of the present invention that will be described herein and will form a part of the subject matter of this specification.

### BRIEF DESCRIPTION OF THE DRAWINGS

In order that the manner in which the above-recited and other advantages and objects of the invention are obtained, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 is a diagram depicting a diagnostic method for detecting cross-wire faults;

FIG. 2 is a diagram depicting a heating system where the heating output is jointly or alternatively provided by any one or more heaters of the heating system; and

FIG. 3 is a diagram depicting the heating system of FIG. 2 with the exception that the heater controllers of heaters A and B have been mis-wired.

### PARTS LIST

2—desired test action
4—decision on whether test action is normal operation
6—act of selecting test action as part of normal operation
8—act of selecting test action as exerciser
10—act of running test action
12—wait time
14—check to determine whether wait time has expired
16—act of getting response of test action from tested device
18—act of getting response of test action from peripheral device
20—tested device or device under test
22—peripheral device
24—component of tested device
26—component of tested device
28—component of peripheral device
30—component of peripheral device
32—act of determining whether response deviates from expected result
34—act of determining whether response deviates from expected result
36—test action database
38—result indicating tested device fault
40—result indicating peripheral cross-wire fault
42—heating system
44—heater
46—heater controller
48—incorrectly connected wire or wire harness
50—igniter
52—temperature sensor
54—burner
56—valve/flow sensor/inlet temperature sensor package
58—heat exchanger
60—incorrectly connected wire or wire harness
62—controller
64—communication bus

### PARTICULAR ADVANTAGES OF THE INVENTION

The present diagnostic method is capable of detecting cross-wire faults or identifying anomalies that occur in peripheral devices and associating such event/s to the device under test as cross-wire faults. Compared to conventional diagnostic methods, the present method does not rely on chance discoveries of faults in identifying cross-wire faults.

### DETAILED DESCRIPTION OF A PREFERRED EMBODIMENT

The term “about” is used herein to mean approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by a variance of 20 percent up or down (higher or lower).

A tested device or device under test, as used herein, refers to a device having properties, e.g., output water temperature, water pressure, rate of output water temperature change, etc., that are monitored for performance, potential problems or failures. A device under test can be tested after it has responded to a control input exerted by a controller configured to control the tested device.

A peripheral device, as used herein, refers to a device that is part of a larger system encompassing a tested device or a device under test but is not configured as a matter of normal operation to receive a control input from a controller configured to control a tested device.

An exerciser, as used herein, refers to a diagnostic routine executed or run outside of a normal operation of a tested device. The diagnostic routine may involve deliberately turning on or off one or more components at various times and in various sequences to produce responses or property changes of the tested device such that they may be obtained and evaluated in order to determine whether the responses meet expected results. This diagnostic routine is necessary if the normal operation of a tested device is incapable of producing an unexpected result, especially in a reasonable period of time or usage within which an anomaly in the device response or property is sought.

A “cross-wire” fault, as used herein, is a fault that is not directly related to the device/s, component/s or part/s under test. A “cross-wire” fault occurs due to at least one incorrect connection of a control or power wire to a component of a peripheral device. Although it is also possible for an incorrect connection to be made of a control or power wire to a component of the same device, it is unlikely to occur due to the specializations in connectors, wires or cables for different types of components in a device. For example, in a heating system having more than one heater, a mis-wiring event of a flow valve of a first heater can cause a flow in the second heater as the flow valve of the second heater is opened instead. Without a cross-wire-enabled diagnostic method, this heating system-level fault would not be detected or it would only be detected by alert service personnel that happened to notice discrepancies in the manner in which the first heater and second heater operated.

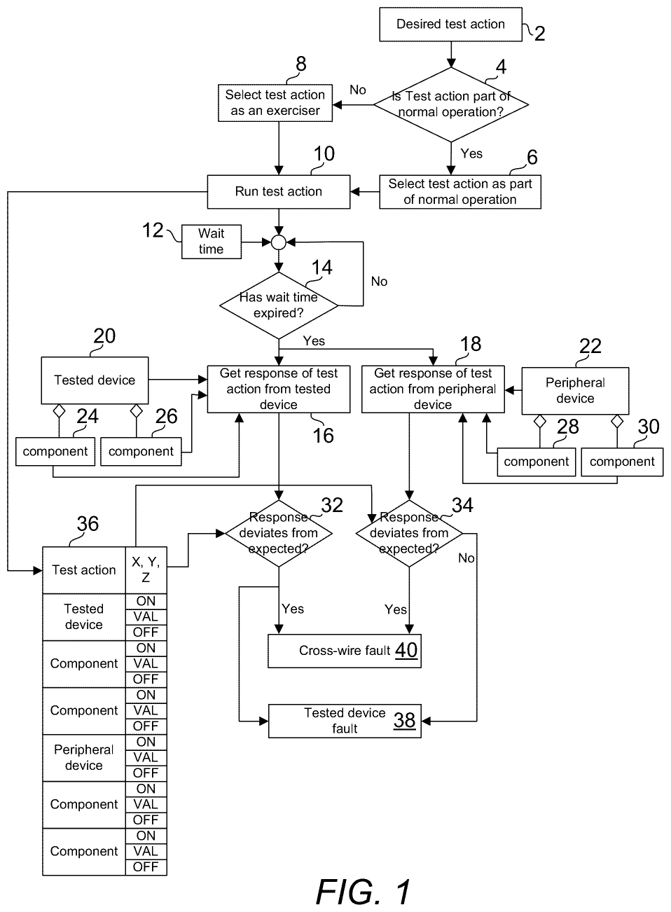

FIG. 1 is a diagram depicting a diagnostic method for detecting cross-wire faults. This diagnostic method is applicable to a system having at least one device under test 20 and at least one peripheral device 22. In general, the diagnostic method includes obtaining a response of a test action 2 conducted on the at least one device under test and obtaining a response of a test action conducted on the at least one peripheral device. If both the response of the test action 2 conducted on the at least one device under test 20 deviates from an expected result based on the test action conducted on the at least one device under test and if the response of the test action conducted on the at least one peripheral device deviates from an expected result based on the test action conducted on the at least one peripheral device, a cross-wire fault is said to have occurred and a cross-wire fault is raised. If the response of the test action conducted on the at least one device under test deviates from an expected result based on the test action conducted on the at least one device under test but the response of the test action conducted on the at least one peripheral device does not deviate from an expected result based on the test action conducted on the at least one peripheral device, a tested device fault is said to have occurred and a tested device fault is raised. In one embodiment, the diagnostic method includes running 6 the test action as part of a normal operation of the at least one device under test. In another embodiment, the diagnostic method further includes running 8 the test action as part of an exerciser. The decision 4 for running a test action as a part of a normal operation or an exerciser can be made at an interface presenting either a normal operation option or an exerciser option to a user or service personnel. If the test action is selected as a normal operation test action, the normal operation of the device under test can proceed normally while the diagnostic routine is activated. If the test action must be run as a part of an exerciser, a normal operation must be prevented from starting once the exerciser is under way. Upon selecting a test action, it can then be run as shown in part 10. When a test action is run as a part of a normal operation, no deliberate efforts have been invested in “creating” or “recreating” a fault and the fault can be obtained simply by running the tested device to deliver a service or product, e.g., heated water, etc., it is designed to do. For some tests, a delay must be allowed before a response can be obtained and analyzed. Here, a wait time 12 is allowed to expire upon starting the test action. Therefore, a check 14 for the expiration of the wait time is required to determine whether it is time to get a response of the test action just run of the tested device and the peripheral device. It shall be noted that, upon expiration of the timer, responses of test actions of the tested device 20 as well as the peripheral device 22 are obtained as shown in steps 16 and 18. In a multi-device system such as one shown in FIG. 1, there can be more than one device. Here, there is only one peripheral device 22 shown although there can be more than one peripheral device 22. The tested device 20 is shown to have two components 24, 26 although, again, there can be one or more than one component in a tested device 20. The peripheral device 22 is shown to have two components 28, 30 although, yet again, there can be one or more than one component in a peripheral device 22. The responses of the test action exerted on the tested device are then compared to the responses obtained from a test action database 36 in step 32.

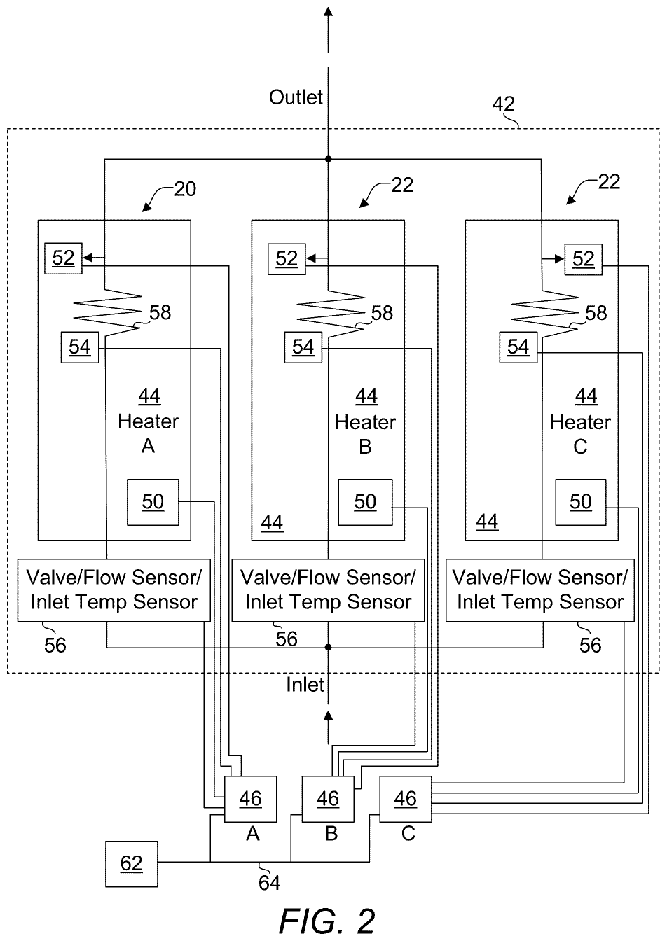

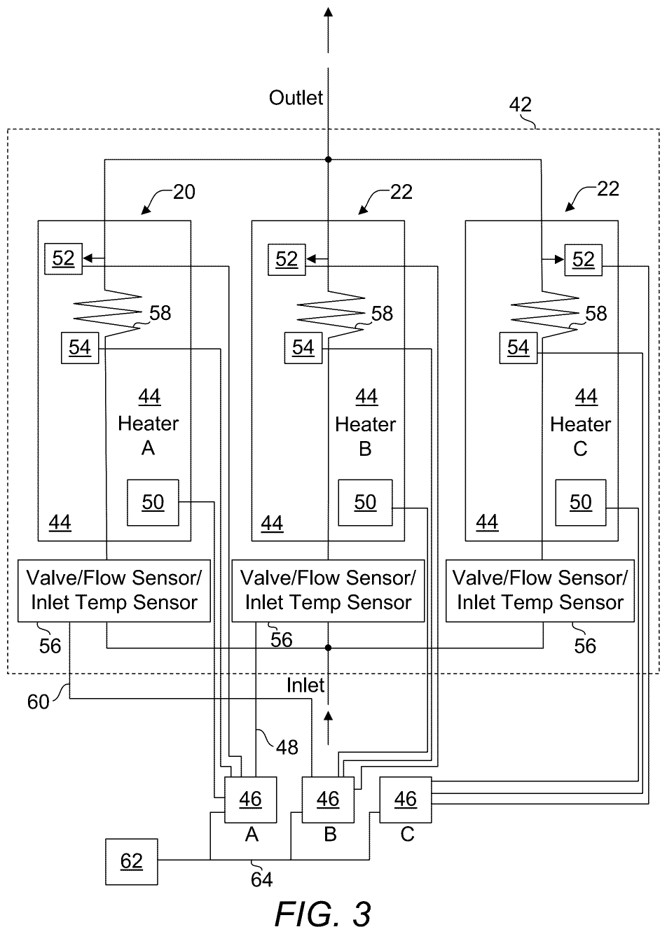

In one embodiment, the database 36 includes information regarding a plurality of test actions, the specific tested devices corresponding to the plurality of test actions and their states and conditions, the specific peripheral devices corresponding to the plurality of test actions and their states and conditions, etc. The response of the test action for the peripheral device is then compared to the responses obtained from a test action database 36 in step 34. If the responses or results of the tested device deviates from the expected response based on the test action exerted on the tested device while the response of the peripheral device does not deviate from the expected response based on the test action exerted on the tested device, a tested device fault 38 is said to have occurred. If the response or result of the tested device deviates from the expected response based on the test action exerted on the tested device while the response of the peripheral device also deviates from the expected response based on the test action exerted on the peripheral device, a cross-wire fault 40 is said to have occurred. It shall be noted that, in the latter combination, both the device under test and the peripheral device do not meet their respective expectations. For instance, if a device under test is commanded to turn on but fails to turn on, the response of the device under test does not meet the test action of turning on the device under test and the response of the peripheral device also fails to meet the test action of turning on the device under test as the peripheral device is now instead turned on when a test action of turning on the peripheral device has not been expected. If the peripheral device alone meets the expectation of not having been turned on and remains in the turned off state, a response of the device under test which does not meet the test action of turning on the device under test can be treated as a fault attributed to the device under test. Details regarding the test actions, components and devices responsible for specific faults shall be provided in the test action database 36 such that upon retrieval of such information pertaining to a specific test action, useful and specific fault information can be provided to service personnel for further corrective actions. An example of a system exhibiting a cross-wire is illustrated in FIGS. 2-3.

FIG. 2 is a diagram depicting a heating system 42 where the heating output is jointly or alternatively provided by any one or more heaters 44 of the heating system 42. If the total hot water demand requested of the heating system 42 can be met using only one of the heaters 44, only one heater 44 needs to be turned on to meet the total hot water demand, otherwise, more than one heater 44 will be turned on to ensure that the total hot water demand requested of the heating system 42, is met. In one example, a total demand is said to have been met when the heating system 42 is capable of providing requested hot water flows at their respective requested flowrates and temperatures. Each heater 44 includes a heat exchanger 58, a burner 54 functionally coupled to it and an igniter 50 for starting the burner 54. Each heater 44 receives a cold water supply via an inlet and supplies heated water via an outlet. A valve/flow sensor/inlet temperature sensor package 56 is provided at the inlet of each heater and an outlet temperature sensor 52 disposed at the outlet of each heater 44 is configured for measuring the water temperature at the outlet of each heater 44. A controller 46 is provided to control each heater 44. All three controllers 46 one for each heater 44, have been substantially co-located. Due to the close proximity of the controllers 46 for heaters A, B and C for ease of service, it is also easy for service personnel to inadvertently mix up at least some of the wires. A connection between the controller 46 of a component, e.g., valve, flow sensor, inlet temperature sensor, igniter 50, burner 54, outlet temperature sensor 52 represents a physical connection, e.g., by wire, between the controller 46 and the component it controls. It shall be noted that, in FIG. 2, the physical connections of the control wires have been properly made, e.g., components of heater A are all connected to controller 46 dedicated for heater A, i.e., controller 46 labelled “A,” components of heater B are all connected to controller 46 dedicated for heater B, i.e., controller 46 labelled “B,” and components of heater C are all connected to controller 46 dedicated for heater C, i.e., controller 46 labelled “C”. According to FIG. 2, if the valve of heater A has been commanded to be disposed in an open position while the burner 54 is also turned on, a water flow will occur through the heat exchanger 58. The temperature sensor 52 will sense an increase in the water temperature. Referring back to FIG. 1, the valve can be seen as the device under test and the test action conducted on the valve includes opening the valve for allowing a flow of water and the response of the test action conducted on the valve includes a temperature response of the flow of water due to the act of opening the valve.

FIG. 3 is a diagram depicting the heating system 42 of FIG. 2 with the exception that the heater controllers 46 of heaters A and B have been mis-wired. More specifically, the heater controllers 46 of heaters A and B have been cross-wired, i.e., the wire or wire harness 60 intended for use in connecting the valve/flow sensor/inlet temperature sensor package 56 of heater A to controller A is inadvertently used in connecting the former to controller B. The wire or wire harness 48 intended for use in connecting the valve/flow sensor/inlet temperature sensor package 56 of heater B to controller B is inadvertently used in connecting the former to controller A. Here, wire 60 should have been used for connecting controller B and heater B. However, due to mis-wiring, controller B is instead connected to the valve of heater A. A mis-wiring has also been made between controller A and heater B. Here, wire 48 should have been used for connecting controller A and heater A. Again, due to mis-wiring, controller A is instead connected to the valve of heater B. A valve turn-on command from controller A will cause the valve of heater B to open. Since the valve of heater A remains closed, the outlet temperature sensor 52 of heater A cannot sense an expected temperature or temperature change after a brief delay. The temperature response of the command for opening a valve as indicated at the outlet temperature sensor 52 therefore does not meet the expected result, e.g., temperature increase, as retrieved from the test action database. The temperature response of the same command that is meant for heater A now causes a flow in heater B. A flow in heater B can cause its outlet temperature sensor to sense a drop or rise in temperature depending on the distribution of residual heat in the water disposed in heat exchanger 58 of heater B. The temperature response of the command for opening a valve in heater A as indicated at the outlet temperature sensor 52 of heater B therefore does not meet the expected result as retrieved from the test action database. As both responses do not meet the expected results, a cross-wire fault is said to have occurred. If the temperature response of the same command for opening a valve of heater A as indicated at the outlet temperature sensor 52 of heater B meets the expected result, e.g., with little to no change in temperature, heater B is treated as behaving according to the valve turn-on command that is only meant for heater A. If the temperature response of the same command for opening a valve of heater A as indicated at the outlet temperature sensor 52 of heater A does not meet the expected result, a fault that points to the valve of heater A is raised such that the valve can be examined further.

Often times, the field environments in which heating systems are installed may be chaotic and field personnel responsible for installing, commissioning, servicing or replacing these systems are subjected to tremendous pressure to get their activities completed with fewest interruptions to the field environments and customers. For instance, in a large hotel with numerous hot water users, it is important to ensure that the availability of hot water is maximized to hotel guests and therefore any interruptions to hot water usage must be minimized. One way to ensure that a replacement performed to the heating system has been successful is to ensure that no heaters have been mis-wired and/or cross-wired. Although only three heaters, i.e., heater A, B and C, are shown in FIG. 3, a heating system prone to mis-wiring or cross-wiring faults, can have many more heaters, e.g., up to twelve heaters. In a heating system with a high number of heaters and in an environment with severe time constraints, it would be impossible for a technician to manually initiate a mis-wiring or cross-wiring fault test to detect such a fault, e.g., if the test or diagnosis involves zooming in on a particular heater that has been mis-wired or a particular pair of heaters that have been cross-wired as there can be many possible heater pairs to be tested. In a three-heater heating system alone, a mis-wiring or cross-wiring condition can be identified on heater pairs A-B, A-C and B-C. In a four-heater heating system, e.g., with heaters A, B, C and D, this number increases to six heater pairs, i.e., heaters A-B, A-C, A-D, B-C, B-D and C-D. In a five-heater heating system, e.g., with heaters A, B, C, D and E, this number increases further to nine heater pairs, i.e., heaters A-B, A-C, A-D, A-E, B-C, B-D, B-E, C-D and C-E. In a six-heater heating system, e.g., with heaters A, B, C, D, E and F, this number increases further to twelve unique heater pairs, i.e., heaters A-B, A-C, A-D, A-E, A-F, B-C, B-D, B-E, B-F, C-D, C-E and C-F. Note that an A-B pairing would be essentially the same as a B-A pairing and only one of these pairings would be used. With every additional heater of a heating system, it can be seen that the number of heater pairs increases by three. Using a controller, a new diagnostic routine for a heater pair can be repeated for a new heater pair upon completion of the previous diagnostic routine until all the diagnostic routines have been completed. In one embodiment, it is possible, for instance, in a six-heater system, to test only A-B, C-D and E-F pairs, i.e., exclusive pairs. However, if a heater fails a test, it can only be classified as a device under test fault and it may be impossible to classify the fault of the heater or its component as a cross-wire fault as appropriate heater pairs were not tested. In one embodiment, if a heater has been confirmed to operate normally, e.g., if a heater has been commanded to provide heating to a water flow, that the heater is capable of bringing the water flow to an expected temperature, e.g., about 180 degrees F., prior to mixing with a cold or unheated water flow or about 125 degrees F., upon mixing with a cold or unheated water flow, within a reasonable period of time, e.g., about 7-30 seconds, it can be exempted from further tests involving it. For instance, in a five-heater heating system, if heater pair A-B has been verified in a diagnostic routine to not possess a mis-wiring fault or a cross-wire fault, neither heater A nor B will be retested in a diagnostic routine involving either heater A or B. Therefore, subsequent diagnostic routines would only need to be performed on heater pairs C-D and C-E, i.e., not heaters A and B which have been previously verified. In one embodiment, in the interest of completing the verification routines disclosed elsewhere herein, in a timely manner, a controller or computer, e.g., controller 62 is used to determine the verification routines that are required to detect mis-wiring and/or cross-wiring faults. The role of controller 62 as a control device for controllers 46, can alternatively be assigned to a controller 46 as long as each controller 46 has knowledge of other controllers 46 and is configured to have authority over other controllers 46 in a certain mode of operation, e.g., during a mis-wiring or cross-wiring fault test, e.g., for one controller 46 to issue a command that drives a component of another controller 46. For simplicity sake, the mechanism useful for determining the tests to run will be described as if there is a separate controller, e.g., controller 62, useful for dispensing test commands to each controller 46 to run tests involving each active heater 44. An active heater is used herein to mean a heater that has been intended to be put in service and that its controller 46 has been successfully connected to the communication bus 64 used by all other controllers 46 of active heaters 44 in a system. As disclosed elsewhere herein, it is unnecessary to perform verification routines on all possible combinations of heaters. In carrying out the verification routines, the active heaters 44 in the heating system would need to be first identified to determine the verification tests that are required for pairs of heaters 44. For instance, upon power up of each controller 46, communication messages from each controller 46 may be dispensed onto the communication bus 64 shared by all the controllers 46 and controller 62, periodically or on request. This communication bus 64 can be a wired bus or a wireless bus, e.g., by means of one of commonly-used communication protocols, e.g., WiFi, Bluetooth®, and Zigbee®, etc. Controller 62 is configured to detect active heaters 44 by detecting the availability of heaters via the communication bus 64. For instance, a message is first dispensed onto the communication bus 64 to request that all active heaters 44 to respond with a message acknowledging their presence. Upon collecting all active heaters 44 to be tested, controller 62 then determines unique pairs of heaters 44 to be tested to avoid redundant and unnecessary tests. For instance, all possible pairs for testing will be formed and each pair will be compared to other pairs to determine whether both members of the pair exist in another pair. If they do, only one of the repeated pairs is used in the list of pairs to be tested. As disclosed elsewhere herein, it is possible to reduce the number of tests by using controller 62 to remove a heater from a further test once it has been verified to be functioning properly. Therefore, any further heater pair involving the verified heater will be removed. If there is only one heater left to be verified as all other heaters have been verified to be functioning according to specification, instead of performing a test on a heater pair, the remaining heater can be tested singly. In this case, the test will either result in the heater being verified as functioning according to specification or the heater being labelled as faulty.

At a higher level, the present diagnostic method can be applied at the device level. In other words, the identification of a cross-wire fault can be used to pinpoint the devices that are potentially involved in a cross-wire fault. Using the same example shown in FIGS. 2-3, if the device under test is a heating device or heater and the test action conducted the device under test includes turning on the device under test, a cross-wire fault can cause a peripheral heating device to turn on instead. Without a present diagnostic method, a mis-wiring event can have severe and long-lasting consequences. For instance, if the mis-wiring event had allowed cross-wired heaters A and B to otherwise function to meet heating demands, true usages on the heaters may not have been reflected by their respective usage data and the maintenance or replacement of parts could be performed on the wrong heater and not on the heater requiring it. The diagnostic method can be executed using any one of the controllers 46 or any remote controller or computing device configured to have access to the properties of the tested device and peripheral devices, test action database and control inputs, e.g., of the controller 46 corresponding to the tested device.

The detailed description refers to the accompanying drawings that show, by way of illustration, specific aspects and embodiments in which the present disclosed embodiments may be practiced. These embodiments are described in sufficient detail to enable those skilled in the art to practice aspects of the present invention. Other embodiments may be utilized, and changes may be made without departing from the scope of the disclosed embodiments. The various embodiments can be combined with one or more other embodiments to form new embodiments. The detailed description is, therefore, not to be taken in a limiting sense, and the scope of the present invention is defined only by the appended claims, with the full scope of equivalents to which they may be entitled. It will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present disclosed embodiments includes any other applications in which embodiments of the above structures and fabrication methods are used. The scope of the embodiments should be determined with reference to the appended claims, along with the full scope of equivalents to which such claims are entitled.

What is claimed herein is:

1. A diagnostic method of a system having a controller, two or more heating devices each having a heat exchanger, a valve disposed upstream of the heat exchanger, and a temperature sensor disposed downstream of the heat exchanger, said diagnostic method comprising, using the controller to:
(a) identify active heating devices of the two or more heating devices in the system to result in two or more active heating devices;
(b) determine at least one test to be performed on said two or more active heating devices, said at least one test involves a unique pairing of said two or more active heating devices, wherein said unique pairing comprises a first heating device comprising a first valve and a first temperature sensor and a second heating device comprising a second valve and a second temperature sensor;
(c) send a first command to open the first valve, obtain a response of the first heating device as indicated by the first temperature sensor to said first command and determine the existence of a first temperature rise as indicated by the first temperature sensor, wherein if the first temperature rise does not exist, a first deviation exists; and
(d) send a second command to open the second valve, obtain a response of the second heating device as indicated by the second temperature sensor to said second command and determine the existence of a second temperature rise as indicated by the second temperature sensor, wherein if the second temperature rise does not exist, a second deviation exists, wherein if both said first deviation and said second deviation exist, a cross-wire fault is raised and if only one of said first deviation and said second deviation exists, a device under test fault is raised; and
(e) repeat steps (c)-(d) until said at least one test has been completed.

2. The diagnostic method of claim 1, further comprising sending a first command to open the first valve as part of a normal operation of the first valve.

3. The diagnostic method of claim 1, further comprising sending a first command to open the first valve as part of an exerciser.
